(19) United States
(12) Patent Application Publication
(10) Pub. No.: US 2007/0168792 A1
(43) Pub. Date: Jul. 19, 2007

(54) Method to Reduce Leakage Within a Sequential Network and Latch Circuit

(75) Inventors: Harry Barowski, Boeblingen (DE); Tobias Gemmeke, Boeblingen (DE); Christian Jacobi, Schoenaich (DE); Matthias Pflanz, Schoenaich (DE)

Correspondence Address: INTERNATIONAL BUSINESS MACHINES CORPORATION, IPLAW DEPARTMENT, 2455 SOUTH ROAD - MS P386, POUGHKEEPSIE, NY, 12601, US

(73) Assignee: INTERNATIONAL BUSINESS MACHINES CORPORATION, Armonk, NY (US)

(21) Appl. No.: 11/566,462

(22) Filed: Dec. 4, 2006

(30) Foreign Application Priority Data
Dec. 9, 2005 (EP) 05111925.3

(51) Int. Cl. G01R 31/28

(52) U.S. Cl. 714/724

(57) ABSTRACT

A method to reduce leakage within a sequential network comprising at least one latch and a combinatorial logic proximate to said latch, by applying an input vector on said sequential network during idle mode is described, the method comprising the steps of: overriding a static feedback of a latch comprising a static feedback loop with an input vector, and setting said sequential network into idle mode. Furthermore a latch circuit comprising a static feedback loop, to be used to perform said method is described, wherein said latch circuit comprises means to override a static feedback within said static feedback loop with an input vector before falling in idle mode.

### BACKGROUND OF THE INVENTION

The invention relates to a method to reduce leakage within a sequential network by input vector control.

Power consumption is one of the key design issues of modern high-performance designs of sequential networks comprising combinatorial logic circuits plus storage elements such as flip-flops and the like, wherein in a sequential network every node is updated in parallel at each step. Thereby a flip-flop typically comprises a latch circuit that is a logic circuit used to store one or more bits. A latch has a data input, a clock input and an output. When the clock input is active, data on the input is latched or stored and transferred to the output either immediately or when the clock input goes inactive. The output will then retain its value until the clock goes active again. Each latch can be seen as a node in the sequential network. Latches typically are integrated circuits comprising several transistors, each one consuming electric power. Due to this, sequential networks comprise plenty of transistors causing power consumption. As technology scales down, the supply voltage must be reduced in a way that dynamic power can be kept at reasonable levels and power delivery can still be performed within the functional requirements. In order to prevent the negative effect on performance incurred, the threshold voltage of the transistors within the sequential network must be reduced at the same rate so that a sufficient gate override is maintained.

The threshold voltage of a transistor, such as a Metal Oxide Semiconductor Field Effect Transistor (MOSFET) is usually defined as the gate voltage where a depletion region forms in the substrate of the transistor. For example in an n-type Metal Oxide Semiconductor (NMOS) the substrate of the transistor is composed of p-type silicon which has more positively charged electron holes compared to electrons. When a voltage is applied on the gate, an electric field causes the electrons in the substrate to become concentrated at the region of the substrate nearest the gate causing the concentration of electrons to be equal to that of the electron holes, creating a depletion region.

The total power consumption of a sequential network can be split in a dynamic part and a static part. The dynamic part is consumed in processing, whereas the static part is wasted during idle times. Thereby the reduction of threshold voltage leads to about a five times increase of static power consumption per technology generation. Nowadays, it can take as much as 50% of the total power budget.

The physical mechanism for static power dissipation is leakage current. Its major contributor is the so called sub-threshold current or sub-threshold leakage of transistors. Sub-threshold leakage is the current that flows from the drain to source of a transistor when the transistor is supposed to be off. Depending on the technological parameters, gate leakage can be an even larger share in static power dissipation in the future.

There are two basic approaches to reduce the static power dissipation by limiting the sub-threshold current. One is to adapt the technology appropriately. Assuming that the technique is already optimally tuned, it only remains the other approach to apply circuit techniques. Circuit techniques can be grouped into the following approaches:
a) static or dynamic modification of the bulk potential,
b) static or dynamic changes to the supply voltage like reducing or switching-off individual gates or blocks,
c) increased stack size of gates,
d) application of dedicated input vector combinations, i.e. bit-stream patterns in idle times. Such a vector minimizes leakage by setting the circuit in its state of minimal power dissipation. In this way, the difference in leakage currents of p-type Metal Oxide Semiconductor (PMOS) and NMOS transistors and/or the existing transistor stacks, i.e. at least two in serial connected transistors, are exploited for low power operation.

These approaches have the following advantages and disadvantages:
The use of additional bulk/channel contacts to be used to modify the bulk potential is very costly in Silicon-On-Insulator (SOI)-technologies with respect to area, speed and yield. In bulk technologies the large parasitic bulk capacitance leads to long transition times with large power consumption.
b) A power switch to be used e.g. to switch-off individual gates basically behaves like on additional stack transistor. Hence, it significantly reduces speed due to the added transistor channel. Certainly, very large switching devices have small resistance but at the same time they lead to high power dissipation when switching their gate capacitance during idle times. Dynamically reducing supply voltage is nowadays neither power efficient nor fast enough.
c) Is equivalent to b) with additional stack transistor instead of a power switch, i.e. smallest grain power supply switching. Basically, there exist three different approaches regarding b) and c):
   An additional sleeping device is used to cut off the gate.
   The transistors are duplicated while trying to keep circuit speed constant, i.e. increasing propagation delay.
   The transistors are duplicated while trying to keep circuit speed constant, i.e. increasing dynamic power dissipation.
In contrast, the application of a dedicated input vector exploits the existing transistor stacks. Of course, the additional switching to the state of the low leakage input vector adds to the total power dissipation. Hence, there is a certain minimal idle time until this technique pays off like it is the case for the other dynamic techniques of a) and b).

In modern high-performance designs it is desired to apply clock gating on a single cycle basis to minimize dynamic power consumption. For this single-cycle switching the application of input vectors is a feasible solution to cope with these frequent mode transitions between active and idle or sleep mode.

Various publications have shown that a dedicated input vector can reduce leakage power between 20% and more than 90% compared to an average figure. The gain of this method strongly depends on the logic depth of the circuit. High performance designs typically feature a small logic depth of less than 20 Fanout-Of-4-Inverters (FO4)-delay. FO4-delay is a measure for estimating circuit delays.

A rough estimate is to assume that 50% of the total power consumption is static and a conservative 20% of this could be reduced. Hence, the total power consumption could be reduced by at least 10% by application of an input vector during sleep mode.

Thereby methods like random search or genetic algorithms have been proposed to determine the optimal input vector.

The major problem is still the power efficient application of the optimal input vector to the circuit of the sequential network or at least to parts of it. This can be done by modification of the circuit—typically at the latch nodes. Thereby a sequential network comprises at least one latch and a combinatorial logic proximate to said latch.

The following solutions have been proposed:
I) Use of an additional transmission gate to cut off the output of a register or any other gate and impose the intended logic value [Halter et al 1997; A Gate-Level Leakage Power Reduction Method for Ultra-Low-Power Complementary Metal Oxide Semiconductor (CMOS) Circuits; IEEE Custom Integrated Circuits Conference 1997, p. 475-478].
II) A similar circuit as described under I) has been proposed for a simple inverter or any other gate [Tsai et al 2004; Characterization and Modeling of Run-Time Techniques for Leakage Power Reduction; IEEE Transactions on very large scale integration (VLSI) Systems, Vol. 12, No. 11, November 2004, p. 1221-1233]. It features additional stack transistors to reduce the leakage of the inverter.
III) Exploiting an existing scan path to pipe in the corresponding input vector over the scan chain. A scan path is a technique used to increase the controllability and observability of a sequential network by incorporating scan registers into the circuit. Normally these act like flip-flops but they can be switched into a “test” mode where they all become one long shift register. This allows data to be clocked serially through all the scan registers and out of an output pin at the same time as new data is clocked in from an input pin. Using this technique, the state of certain points in the circuit can be examined and modified at any time by suspending normal operation and switching to test mode.
IV) Extending the multiplexers of a scan path to override the scan signal locally with a required bit of a corresponding input vector [Abdollahi et al 2003; Leakage Current Reduction in Sequential Circuits by Modifying the Scan Chains; IEEE 2003]. Thereby it is proposed to apply an input vector causing a minimum leakage by a modified scan chain, wherein a latch with extra flip-flops is used for state recovery.

The drawbacks of these solutions are that:
I) and II) increase the delay of the timing critical path as they either introduce another switch, e.g. a transmission gate, or add transistors to the stack. In both cases the output load is increased by a tie-up and tie-down transistor, respectively, i.e. the transistors required for the additional transmission gate.
III) can only be used in case of very long idle times. Additional Read-Only-Memory (ROM) is required to store the input vectors. Special control logic has to scan in the low leakage vectors to the specific idle blocks.
IV) combines the advantage of local storage of the input vector and the invariance of the timing critical path. To restore a prior value it requires additional registers. The control logic must be able to activate the scan chain for the idle sub-blocks only in order to apply the dedicated input vector.

In summary , the existing solutions either change the critical path or require a significant control overhead combined with longer minimal idle times. Also, the increased load on the timing critical path leads to higher dynamic power consumption. This again increases the minimal idle time until the approach pays off in terms of total power consumption.

### BRIEF SUMMARY OF THE INVENTION

It is therefore an object of the invention to provide a method to apply an input vector during idle mode on a sequential network without influencing the overall performance of said sequential network, wherein said input vector causes a minimal leakage current within said sequential network during idle mode.

Another object of the invention is to provide a latch circuit being part of a sequential network to be used to apply a input vector on said sequential network, or at least on parts of said network, wherein additional means of said latch to be used to apply said input vector have minimal influence on performance of said sequential network.

The object of the invention is achieved by the proposed method to reduce leakage within a sequential network, said sequential network comprising e.g. a latch stack with at least one latch and a combinatorial logic proximate to said latch, by applying an input vector on said sequential network during idle mode, wherein said method comprises the steps of:

overriding a static feedback of a latch comprising a static feedback loop with an input vector comprising a pattern causing a low leakage current in said sequential network during idle mode; and

setting said sequential network into idle mode.

Said method according to the invention has the advantage over the state of the art, that the overriding of the static feedback within the feedback loop of the latch can be done with minimal influence on the signal path. Also there is minimal control overhead necessary, since this method is easy to realize within a latch comprising a static feedback loop by using only a few, particularly only two, additional transistors in the feedback loop. Thereby the static feedback preferably is overridden by looping said input vector into said static feedback loop of said latch.

This method according to the invention reduces this current while leaving dynamic power dissipation unchanged. However, it can be combined with any other static or dynamic power saving methodology. Hence, it is one key step to solve the power consumption problem of modern sequential network technologies.

According to a preferred embodiment of said method, the looping in of said input vector into the feedback loop of said latch and the falling in idle mode of at least that latch is forced by a control signal.

In a preferred embodiment of said method according to the invention, said latch is forced to forward said input vector to said combinatorial logic before setting said sequential network into idle mode. Preferably said latch is forced by a control signal to forward said input vector to said combinatorial logic.

In another preferred embodiment of said invention, said input vector to be used to override said static feedback of said latch is generated on spot by a dedicated circuit being connectable with said static feedback loop in the very moment said circuit receives a control signal. Doing so, only a very small control overhead is required, since the input vector has not to be stored anywhere and is generated directly on spot.

In an additional preferred embodiment of said invention, said control signal is derived from a clock signal also used during normal mode to forward signals stored within a latch stack comprising at least two latches from a first latch to a second latch along a signal path. Doing so, switching to idle mode can be done as quickly as clock gating, i.e. on a single clock cycle basis. Furthermore this technique requires only minimal control overhead, since the control signal has not to be generated laborious.

A particularly preferred embodiment of said invention is characterized in that the overridden value of the latch is restored after idle mode. This allows awaking the sequential network from idle mode to normal mode without performance loss.

In an additional preferred embodiment of said invention, the retrieval of the overridden value of the latch is done by first awaking the latch with the input vector looped in by the clock signal, and second awaking the latch in front of the latch with the input vector looped in, also by the clock signal. Doing so, the latch with the input vector looped in gets its old value held before idle mode from the latch in front of it. This latch is the last latch proximate to the combinatorial logic and retrieves its overridden old value from the latch arranged in front of it within the stack, when awaking from idle mode.

A preferred embodiment of this invention concerns a latch circuit comprising a static feedback loop, to be used to perform the method according to the invention, said latch circuit comprising means to override a static feedback within said static feedback loop with an input vector before falling in idle mode. Thereby said input vector comprises a pattern causing a low leakage current in a sequential network comprising said latch circuit during idle mode.

An advantage of the invention is that a new type of latch circuit is achieved, which is based on a standard static latch circuit. In such a standard latch type all latch nodes are regenerated by static feedback loops comprising static feedback inverters, wherein the feedback is disrupted when new data is written to the latch. The invention proposes to override the static feedback with an input vector e.g. generated by a control signal and to force the value of the corresponding low leakage pattern during idle times. This approach combines the following advantages:
No change in the timing critical path.
The idle mode is controlled by a single control signal, which can be derived from the clock gating signal. Hence, this technique requires a minimal control overhead.
Only two additional transistors are required in the latch, i.e. the overhead in transistor count is about 8%. The increase in area is even less, as the additional transistors are of minimal size.
If necessary the latch can even return to its original state requiring specific clock activation after the idle times.
The stability of the latch nodes is unchanged.
During non-idle operation the latch is fully compatible with standard latches. Tying the idle signal to ground basically converts an enhanced low leakage latch back to the traditional one.
Switching from and to idle mode can be done as quickly as clock gating, i.e., on a single cycle basis.

The derivation of the low leakage patterns can be done by any algorithm like e.g. random search [Tsai et al 2004; Characterization and Modeling of Run-Time Techniques for Leakage Power Reduction; IEEE Transactions on very large scale integration (VLSI) Systems, Vol. 12, No. 11, November 2004, p. 1221-1233] or heuristics like the genetic algorithm [Chen et al 1998; Estimation of Standby Leakage Power in CMOS Circuits Considering Accurate Modeling Transistor Stacks; Proc. International Symposium on Low Power Electronics and Design, 1998, pp. 239-244]. To simplify the search the pattern respectively the input vector comprising the pattern can be split into subsets of independently controlled logic.

Thereby the logic pattern can either be dynamically loaded or fixed during logic design. The former requires additional circuitry and the ability to force high and low, respectively.

A preferred embodiment, of said latch circuit according to the invention is characterized in that said means to override said static feedback comprise means to loop said input vector into said static feedback loop of said latch circuit.

Another preferred embodiment of said latch circuit comprises means to generate said input vector, wherein said means are connectable with said static feedback loop. Thereby said means to generate said input vector preferably are connected with the static feedback loop in the very moment a control signal preparing to activate idle mode is received.

In a preferred embodiment of said latch circuit, said means to generate said input vector comprise a dedicated circuit generating said input vector in the very moment when receiving a control signal preparing the activation of the idle mode, wherein said dedicated circuit is connectable with said static feedback loop of said latch circuit via switch being switched by said control signal.

A preferred embodiment of said latch circuit comprises means to forward said input vector to a combinatorial logic connected with the output of said latch circuit before falling in idle mode. As known standard high-performance latches do not allow output forcing, they do not fulfill an elementary requirement needed to reduce leakage current. In contrast, the latch according to the invention allows forcing to forward said input vector to the combinatorial logic.

In another preferred embodiment of said latch circuit, said latch circuit is the last latch along a signal path towards a combinatorial logic. Thereby said latch circuit preferably is the last latch within a latch stack comprising at least two latches.

A preferred embodiment of said latch circuit comprises means to derive a control signal to be used to prepare activation of idle mode from a clock signal usually being used to synchronize the switching of several latches arranged along a signal path within a latch stack.

A particularly preferred embodiment of said latch circuit according to the invention is characterized in that the additional elements like said means to generate said input vector, and/or said means to override said static feedback, and/or preferably said means to forward said input vector, and/or said means to derive a control signal are arranged outside the signal path.

### BRIEF DESCRIPTION OF THE DRAWINGS

The present invention and its advantages are now described in conjunction with the accompanying drawings.

FIG. 1 is showing a schematic circuit block diagram of a modified latch according to the invention, being arranged in a latch stack that is part of a sequential network,

FIG. 2 is showing a schematic circuit block diagram of a static scan latch according to the state of the art, being arranged in a latch stack that is part of a sequential network, and

FIG. 3 is showing a schematic circuit diagram according to a method according to the invention.

### DETAILED DESCRIPTION OF THE INVENTION

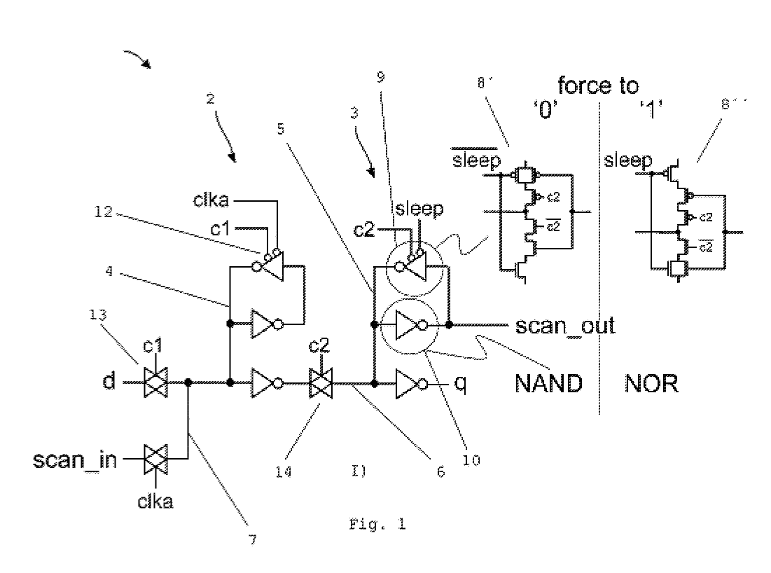

As shown in FIG. 1, a latch stack 1 comprises two latches 2, 3, each one comprising a static feedback loop 4, 5. A signal path 6 is passing the latch stack 1 from the input node d to the output node q. A combinatorial logic (not shown) is arranged proximate to the last latch 3 and is connected with the output node q of the latch stack 1.

Furthermore the latch stack 1 features a scan chain 7, schematically displayed by the markings ‘scan_in’ and ‘scan_out’. The latch stack 1 and combinatorial logic are part of a sequential network.

A clock signal generator (not shown) is used to generate clock signals c1, c2, clka. The clock signals c1, c2 are used to clock the latches 2, 3 within the latch stack 1 during normal mode. The clock signals c1 and c2 are further used to trigger transmission gates 13, 14 that are parts of the latches 2, 3. During scan mode, the clock signal clka and the clock signal c2 are used.

To override the static feedback it is foreseen to loop an input vector comprising a pattern that causes a minimal leakage current within the sequential network during idle mode into the static feedback loop 5 of the latch 3.

This is done by using a control signal ‘sleep’. This control signal ‘sleep’ is fed into a dedicated circuit 8′, 8″, wherein the dedicated circuit 8′, 8″ automatically generates the desired input vector on spot at the static feedback loop. The dedicated circuit 8′, 8″ is integral part of the component 9 shown in FIG. 1 I. With this proposed latch type according to the invention the low leakage patterns are fixed during logic design. When the control signal ‘sleep’ is active, the clock signals c1, c2 preferably are off.

Two possible dedicated circuits 8′, 8″ are shown in FIG. 1 II and FIG. 1 III. Thereby the dedicated circuit 8′ in FIG. 1 II forces a ‘0’, wherein the dedicated circuit 8′ in FIG. 1 III forces a ‘1’ on node q. By using a dedicated circuit, 8′, 8″ it has to be determined during design, if the dedicated circuit forces a ‘0’ or ‘1’.

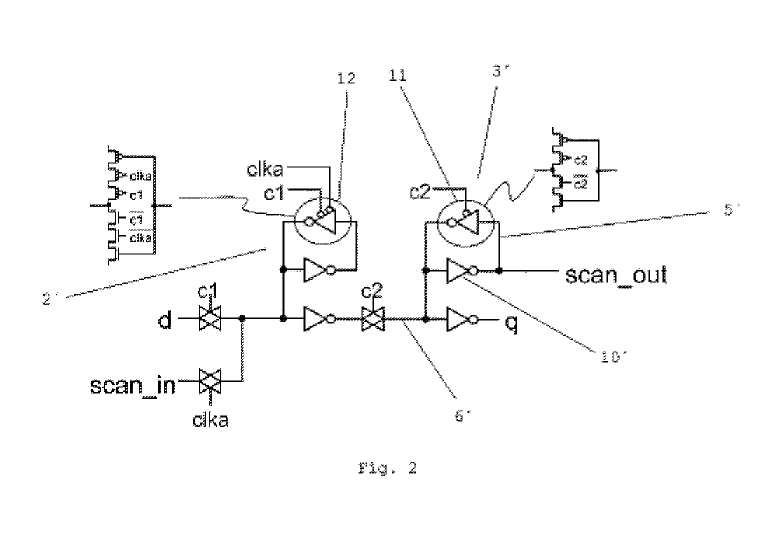

Compared with the static scan latch 3′ according to the state of the art shown in FIG. 2, the latch 3 according to the invention is only modified within the inverter 11 in FIG. 2 that becomes the component 9 in FIG. 1, both arranged outside the signal path 6′, 6, respectively.

The same effect can be reached by replacing the inverter 10′, 10 in FIG. 2, FIG. 1 I, respectively, by a NAND gate to force a ‘0’ on node 1 (FIG. 1 II) or by a NOR gate to force a ‘1’ on node q (FIG. 1 III), wherein the solution described above is preferred solution, since replacing the inverter 10, 10′ respectively, raises the load on node q.

Both thinkable modifications apply to the second feedback-loop 5′ shown on the top-right of FIG. 2. As a function of the optimal input vector:

a) either the Clocked CMOS (C2MOS) inverter 11 is modified

b) or the inverter 10′ is replaced by an NAND and NOR, respectively as shown in FIG. 1.

Thereby it is important to note that

The modified C2MOS-Inverter 11 (FIG. 2), that is after modification a C2MOS-Gate 9, 8′, 8″ (FIG. 1), is at least as good as the C2MOS-Inverter 12, 12′ of the first latch 2, 2′. Hence, there is no degradation in the overall stability of the latch nodes.

The load on the timing critical path remains unchanged by this modification, as the transistors are not seen by the critical path during signal propagation.

The switching to and from idle mode does not influence circuit behavior. However the intended state of the circuit in idle mode may take up to a complete cycle until the signal is propagated. This is the case for any technique applying dedicated input vectors. However, this is still much faster than dynamic changes to supply voltage or bulk potential.

Restoring to the original latch state can be done by a special recovery from the idle time. The c1-clock has to be low during all idle time. The c2-clock may or may not be switching after the c1-clock before the idle period. However, it has to be switched off during the idle period, too. Recovery is started by clocking c2 first. In this way, the second latch is set to the (inverted) value stored in the first latch (reference numeral 2 in FIG. 1).

In general it is thinkable to integrate any combinatorial logic between the latches 2, 3. In FIG. 1 the simplest thinkable logic is shown, wherein inverters are arranged between the latches 2, 3 and between the last latch 3 and the node q.

Moreover, this technique can be combined with Multi-Threshold CMOS (MTCMOS) or increased stack sizes. Those approaches decrease leakage by increased threshold voltage of stack size in none critical paths. In combination with a dedicated input vector the set of the devices that need to be modified is reduced, as the logic input of each gate is known a-priori and fixed during idle times.

Finally, the invention proposes to transform additionally any transmission gate into a C2MOS-gate. At least, in the scan path this will not lead to any speed loss. Also the simple inverters in the feedback-loops might be replaced by so called long-channel devices or inverters, which are MOSFETS with a long gate channel with duplicated NMOS and PMOS to reduce leakage there, too.

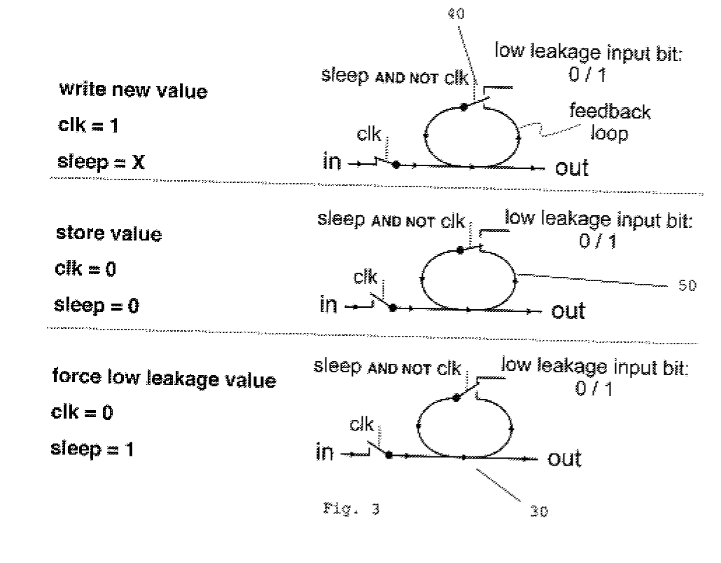

The execution of the method according to the invention can be easily understood regarding FIG. 3. In normal mode, a new value is written into the latch 30 every time the clock signal clk is high (clk=1). This functionality is independent of the state of the control signal as shown symbolically by ‘sleep=X′. The new value is stored within the static feedback loop 50 in the very moment the clock signal clk is low (clk=0). When idle mode is activated, a low leakage input vector comprising a low leakage input bit is looped into the static feedback loop 50 by switching a switch 40. Thereby the activation of idle mode is symbolic shown by ‘sleep=1’. The input bit can be a ‘0’ or a ‘1’, depending on the design of the circuit. The generation of the input vector and the switching of the switch 40 preferably are initialized by a control signal derived from the clock signal.

It is important to mention that the invention proposes to apply leakage reduction by exploiting the stack effect. For this purpose it proposes to combine the preferably automatic derivation of input vectors comprising optimal patterns for minimal leakage and the preferably automatic instantiation of dedicated latches including the choice of the specific low leakage patterns.

The low leakage pattern can be applied during idle times as short as a single clock cycle but of arbitrary length. For this purpose it is proposed to use a newly introduced or an existing clock gating signal to steer the force mechanism.

While the present invention has been described in detail, in conjunction with specific preferred embodiments, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

What is claimed is:

1. Method to reduce leakage within a sequential network comprising at least one latch and a combinatorial logic proximate to said latch, said method comprising the steps of:
applying an input vector on said sequential network during idle mode;
overriding a static feedback of a latch comprising a static feedback loop with the input vector; and
setting said sequential network into idle mode.

2. Method according to claim 1 wherein said input vector is looped into the static feedback loop of said latch.

3. Method according to claim 2 wherein the looping in of said input vector is forced by a control signal.

4. Method according to claim 1 wherein said latch is forced to forward said input vector to said combinatorial logic before setting said sequential network into idle mode.

5. Method according to claim 4 wherein said latch is forced by a control signal to forward said input vector to said combinatorial logic.

6. Method according to claim 3 wherein said input vector is generated by a dedicated circuit in the very moment said circuit receives a control signal.

7. Method according to claim 3 wherein said control signal is derived from a clock signal.

8. Method according to claim 1 wherein the overridden value of the latch is restored after idle mode.

9. Method according to claim 8 wherein the retrieval of the overridden value of the latch is done by first awaking the latch with the input vector looped in, and second awaking the latch in front of the latch with the input vector looped in.

10. A latch circuit comprising:
a static feedback loop; and
means to override a static feedback within said static feedback loop with an input vector before falling in idle mode.

11. Latch circuit according to claim 10 wherein said means to override said static feedback comprise means to loop said input vector into said static feedback loop.

12. Latch circuit according to claim 10 further comprising means to generate said input vector, wherein said means are connectable with said static feedback loop.

13. Latch circuit according to claim 12 wherein said means to generate said input vector comprise a dedicated circuit generating said input vector in the very moment when receiving a control signal and wherein said dedicated circuit is connectable with said static feedback loop via a switch being switched by said control signal.

14. Latch circuit according to claim 12 further comprising means to forward said input vector to a combinatorial logic connected with said latch circuit.

15. Latch circuit according to claim 10 wherein said latch circuit is the last latch along a signal path towards a combinatorial logic.

16. Latch circuit according to claim 14 further comprising means to derive a control signal to be used to prepare activation of idle mode from a clock signal usually being used to synchronize the switching of a plurality of latches arranged along a signal path within a latch stack.

17. Latch circuit according to claim 16 wherein one or more of said means to generate said input vector, said means to override said static feedback, said means to forward said input vector, and said means to derive a control signal are arranged outside the signal path.

18. Latch circuit according to claim 10 further comprising means to derive a control signal to be used to prepare activation of idle mode from a clock signal usually being used to synchronize the switching of a plurality of latches arranged along a signal path within a latch stack.

19. Latch circuit according to claim 10 wherein one or more of said means to generate said input vector, said means to override said static feedback, said means to forward said input vector, and said means to derive a control signal are arranged outside the signal path.

20. Method according to claim 1 wherein said input vector is generated by a dedicated circuit in the very moment said circuit receives a control signal.
